(19) United States
(12) Patent Application Publication
(10) Pub. No.: US 2012/0119358 A1
(43) Pub. Date: May 17, 2012

(54) SEMICONDIUCTOR PACKAGE SUBSTRATE AND METHOD FOR MANUFACTURING THE SAME

(75) Inventor: Yoong OH, Gyunggi-do (KR)

(73) Assignee: SAMSUNG ELECTRO-MECHANICS CO., LTD., Gyunggi-do (KR)

(21) Appl. No.: 13/223,147

(22) Filed: Aug. 31, 2011

(30) Foreign Application Priority Data
Nov. 11, 2010 (KR) 10-2010-0112165

(51) Int. Cl. H01L 23/498; H01L 21/56

(52) U.S. Cl. 257/737; 438/127; 257/E23.068; 257/E21.502

(57) ABSTRACT

Disclosed herein is a semiconductor package substrate including: a substrate for package having connection pads; and a solder resist layer formed on one surface or both surfaces of the substrate for package and having openings exposing the connection pads, wherein the solder resist layer includes a roughness layer formed thereon.

### CROSS REFERENCE TO RELATED APPLICATION

This application claims the benefit of Korean Patent Application No. 10-2010-0112165, filed on Nov. 11, 2010, entitled “Semiconductor Package Substrate And Method For Manufacturing The Same” which is hereby incorporated by reference in its entirety into this application.

### BACKGROUND OF THE INVENTION

1. Technical Field

The present invention relates to a semiconductor package substrate and a method for manufacturing the same.

2. Description of the Related Art

Generally, a molding process of a semiconductor package, which is one of the packaging processes of assembling a semiconductor chip manufactured in a wafer state as a semiconductor package, indicates a process of bonding the semiconductor chip to a printed circuit board (PCB) or a leadframe and sealing a product wire bonded using a gold wire using a sealant such as an epoxy molded compound (EMC).

That is, an ultimate object of the molding process is to protect an internal semiconductor chip from external physical, mechanical, and electrical impact and effectively discharge heat generated at the time of operation of the semiconductor chip to the outside.

FIGS. 7 to 10 are process flow charts schematically showing a process of manufacturing a semiconductor package substrate according to the prior art.

A solder resist layer 20 having openings 15 exposing connection pads 11 for semiconductor chip mounting and connection with external components is formed on a printed circuit board 10 on which circuit patterns including the connection pads 11 are formed, as shown in FIG. 7. Then, solder bumps 30 are formed on the connection pads 11 as shown in FIG. 8. Next, a semiconductor chip 40 is mounted on the solder bumps 30 as shown in FIG. 9.

Thereafter, the solder bumps 30 reflows to thereby bond the semiconductor chip 40 to the connection pads 11, and the printed circuit board 10 including the semiconductor ship 40 is then molded an EMC 50 as shown in FIG. 10.

Here, in order to improve adhesion between the EMC 50 and the solder resist layer 20, a chemical or mechanical process is performed on an interface of the solder resist layer 20 to thereby form artificial roughness (not shown). However, when the roughness (not shown) is formed through the above-mentioned process, a filler or a polymer material in the solder resist layer 20 is destroyed, thereby causing various types of defects such as a foreign material defect.

### SUMMARY OF THE INVENTION

The present invention has been made in an effort to provide a semiconductor package substrate in which a roughness layer capable of improving adhesion between a sealing member and a solder resist layer simultaneously with protecting a surface of the solder resist layer is formed, and a method for manufacturing the same.

According to a preferred embodiment of the present invention, there is provided a semiconductor package substrate including: a substrate for package having connection pads; and a solder resist layer formed on one surface or both surfaces of the substrate for package and having openings exposing the connection pads, wherein the solder resist layer includes a roughness layer formed thereon.

The solder resist layer may include a semiconductor chip mounting area and an exposure area in which a surface thereof is exposed to the outside, and the roughness layer may be formed in the exposure area.

The roughness layer may be made of a liquid resin sprayed by an inkjet, and the resin may be epoxy or polyimide.

The semiconductor package substrate may further include bumps formed on the exposed connection pads and a sealing member molding a semiconductor chip mounted on the connection pads and the substrate for package having the semiconductor chip mounted thereon, wherein the sealing member is made of an epoxy molded compound.

According to another preferred embodiment of the present invention, there is provided a method for manufacturing a semiconductor package substrate, the method including: forming a solder resist layer having openings exposing connection pads on a substrate having the connection pads; and forming a roughness layer on the solder resist layer.

The solder resist layer may include a semiconductor chip mounting area and an exposure area in which a surface thereof is exposed to the outside, and the roughness layer may be formed in the exposure area.

The forming of the roughness layer may be performed by spraying a liquid resin on the solder resist layer, wherein the spraying is performed by an inkjet and the resin is epoxy or polyimide.

The method may further include, after the forming of the roughness layer, forming bumps on the connection pads; mounting a semiconductor chip on the bumps; and molding the substrate having the semiconductor chip mounted thereon using a sealing member, wherein the sealing member is made of an epoxy molded compound.

### BRIEF DESCRIPTION OF THE DRAWINGS

FIG. 1 is a cross-sectional view schematically showing a structure of a semiconductor package substrate according to a preferred embodiment of the present invention;

FIGS. 2 to 6 are process flow charts schematically showing a process of manufacturing a semiconductor package substrate according to a preferred embodiment of the present invention; and

FIGS. 7 to 10 are process flow charts schematically showing a process of manufacturing a semiconductor package substrate according to the prior art.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the tem to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

Semiconductor Package Substrate

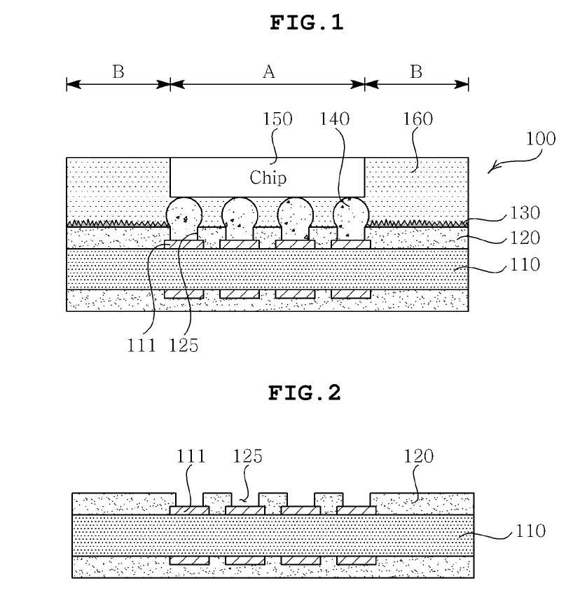

FIG. 1 is a cross-sectional view schematically showing a structure of a semiconductor package substrate according to a preferred embodiment of the present invention.

Although FIG. 1 schematically shows a semiconductor package substrate in a state in which other detailed components of the semiconductor package substrate except for a feature part of a corresponding embodiment is omitted, it may be easily appreciated by those skilled in the art that the present invention is not specifically limited thereto but may be applied to all semiconductor package structures known in the art.

Referring to FIG. 1, a semiconductor package substrate 100 according to a preferred embodiment of the present invention includes a substrate 110 for package having connection pads 111 for semiconductor chip mounting and connection with external components formed thereon and a solder resist layer 120 formed on one surface or both surfaces of the substrate 110 for package and having openings 125 exposing the connection pads 111, wherein the solder resist layer 120 includes a roughness layer 130 formed thereon.

The substrate 110 for package is a printed circuit board having at least one layer circuit including the connection pads 111 formed on an insulating layer. Although a configuration of a specific inner layer circuit is omitted in FIG. 1 for convenience of explanation, it may be easily appreciated by those skilled in the art that a general printed circuit board including at least one layer circuit formed on an insulating layer may be used as the substrate 110 for package.

As the insulating layer, a resin insulating layer may be used. As materials of the resin insulating layer, a thermo-setting resin such as an epoxy resin, a thermo-plastic resin such as a polyimide resin, a resin having a reinforcement material such as a glass fiber or an inorganic filler impregnated in them, for example, a prepreg may be used. In addition, a thermo-setting resin, a photo-setting resin, and the like, may be used. However, the materials of the resin insulating layer are not specifically limited thereto.

In addition, the circuit including the connection pads 111 may be made of any material used as a conductive metal for circuit in a circuit substrate field, and is typically made of copper in the case of a printed circuit board.

The solder resist layer 120, which serves as a protective layer protecting an outermost layer circuit and is formed for electrical insulation, includes the openings 125 formed in order to expose the connection pads 111 of an outermost layer. The solder resist layer 120 may be made of, for example, solder resist ink, a solder resist film, an encapsulant, or the like, as known in the art. However, a material of the solder resist layer 120 is specifically limited thereto.

The exposed connection pad 111 may further include a surface treatment layer (not shown) formed thereon, as needed.

The surface treatment layer may be any surface treatment layer known in the art and be formed through, for example, electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like.

Here, the solder resist layer 120 includes a semiconductor chip mounting area A in which a semiconductor chip is mounted thereon, such that a surface thereof is not exposed to the outside, and an exposure area B in which a surface thereof is exposed to the outside, and the roughness layer 130 may be formed in the exposure area B. That is, the roughness layer 130 is formed on a surface of the solder resist layer 120 contacting a sealing member 160.

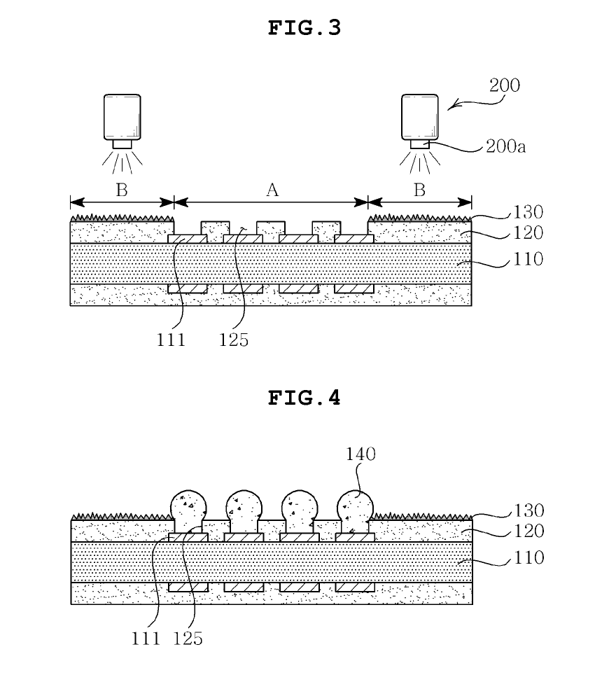

The roughness layer 130 may be formed by, for example, spraying a liquid resin on the surface of the solder resist layer 120 in the exposure area B by a nozzle 200a of an inkjet 200 as shown in FIG. 3. The liquid resin may be epoxy or polyimide; however, it is not specifically limited thereto.

The semiconductor package substrate may further include bumps 140 formed on the connection pads 111 exposed through the solder resist layer 120 and electrically connect the semiconductor chip 150 or external components to the inner layer circuit through the bumps 140.

In addition, the semiconductor package substrate may further include the semiconductor chip 150 mounted on the bumps 140 and the sealing member 160 for molding the semiconductor chip 150 and the substrate 110 for package. Here, the sealing member 160 may be made of an epoxy molded compound. However, a material of the sealing member 160 is not specifically limited thereto.

The semiconductor package substrate according to the preferred embodiment of the present invention includes the roughness layer formed by spraying the liquid resin on the surface of the solder resist layer, thereby making it possible to improve adhesion between the solder resist layer and the sealing member simultaneously with protecting the surface of the solder resist layer.

Method for Manufacturing Semiconductor Package Substrate

FIGS. 2 to 6 are process flow charts schematically showing a process of manufacturing a semiconductor package substrate according to a preferred embodiment of the present invention.

First, referring to FIG. 2, a substrate 110 for package having connection pads 111 exposed by openings 125 of a solder resist layer 120 is prepared.

According to the preferred embodiment of the present invention, the preparing of the substrate 110 for package may include preparing a substrate on which an outermost layer circuit including the connection pads 111 is formed; forming a solder resist layer 120 on the substrate; and exposing the connection pads 111 by forming the openings 125 in the solder resist layer 120.

Here, the opening 125 may be formed by a photolithography method or a laser method including exposure and development.

Then, referring to FIG. 3, a roughness layer 130 is formed on the solder resist layer 120.

Here, the solder resist layer 120 includes a semiconductor chip mounting area A in which a semiconductor chip is mounted thereon, such that a surface thereof is not exposed to the outside, and an exposure area B in which a surface thereof is exposed to the outside, and the roughness layer 130 may be formed in the exposure area B. That is, the roughness layer 130 is formed on a surface of the solder resist layer 120 contacting a sealing member 160.

Here, the roughness layer 130 may be formed by spraying a liquid resin on the surface of the solder resist layer 120 in the exposure area B in an inkjet scheme. That is, as shown in FIG. 3, the roughness layer 130 may be formed by spraying a liquid type of resin on the surface of the solder resist layer 120 in the exposure area B by a nozzle 200a of an inkjet 200. Here, the liquid type of resin may be epoxy, polyimide, or the like; however, it is not specifically limited thereto.

Next, referring to FIG. 4, bumps 140 are formed on the exposed connection pads 111.

According to the preferred embodiment of the present invention, the bumps 140 may be formed by a method such as a general solder paste printing method, a plating method, or the like, as known in the art.

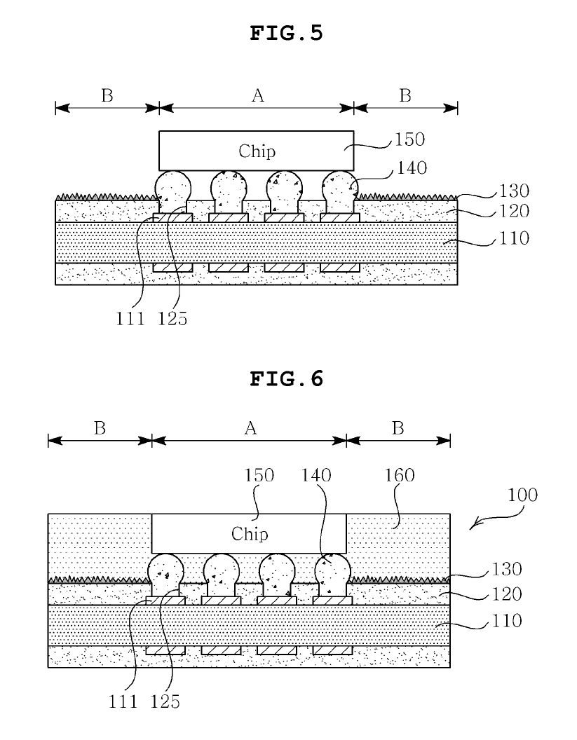

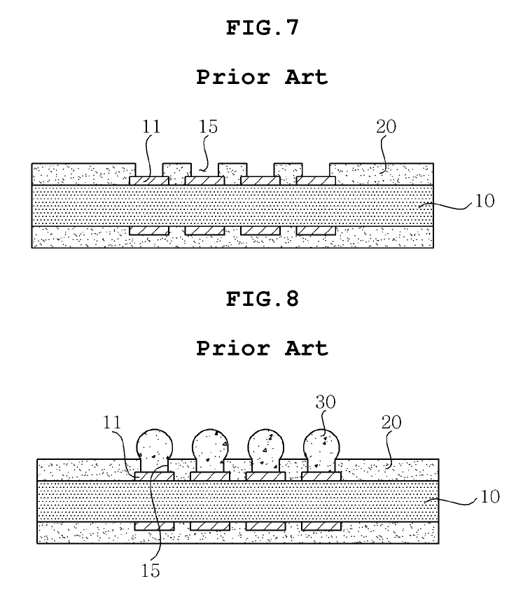

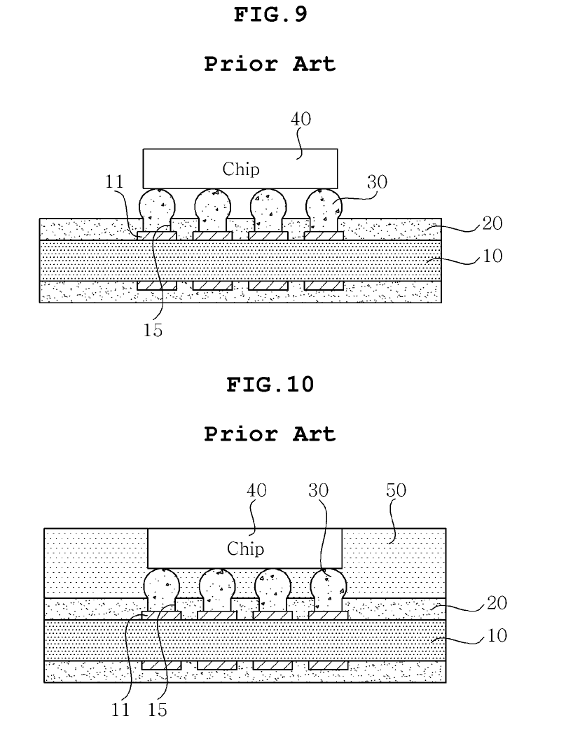

Thereafter, as shown in FIG. 5, a semiconductor chip 150 is mounted on the bumps 140. Here, according to the preferred embodiment of the present invention, the semiconductor chip 150 and the connection pads 111 may be bonded to each other by a reflow process. However, a process of bonding the semiconductor chip 150 and the connection pads 111 to each other is not specifically limited thereto.

Then, as shown in FIG. 6, the substrate 110 for package including the semiconductor chip 150 mounted thereon is molded using the sealing member 160. Here, the sealing member 160 may be made of an epoxy molded compound. However, a material of the sealing member 160 is not specifically limited thereto.

As set forth above, according to the preferred embodiments of the present invention, the liquid resin is sprayed on the surface of the solder resist layer to form the roughness layer, such that a chemical or mechanical process is not directly performed on the solder resist layer, thereby making it possible to protect the surface of the solder resist layer simultaneously with forming the roughness layer.

In addition, the roughness layer is artificially formed on the surface of the solder resist layer, thereby making it possible to improve the adhesion between the sealing member and the solder resist layer.

Although the preferred embodiments of the present invention have been disclosed for illustrative purposes, they are for specifically explaining the present invention and thus a semiconductor package substrate and a method for manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A semiconductor package substrate comprising:
a substrate for package having connection pads; and
a solder resist layer formed on one surface or both surfaces of the substrate for package and having openings exposing the connection pads,
wherein the solder resist layer includes a roughness layer formed thereon.

2. The semiconductor package substrate as set forth in claim 1, wherein the solder resist layer includes a semiconductor chip mounting area and an exposure area in which a surface thereof is exposed to the outside, and the roughness layer is formed in the exposure area.

3. The semiconductor package substrate as set forth in claim 1, wherein the roughness layer is made of a liquid resin sprayed by an inkjet.

4. The semiconductor package substrate as set forth in claim 3, wherein the resin is epoxy or polyimide.

5. The semiconductor package substrate as set forth in claim 1, further comprising bumps formed on the exposed connection pads.

6. The semiconductor package substrate as set forth in claim 1, further comprising a sealing member molding a semiconductor chip mounted on the connection pads and the substrate for package having the semiconductor chip mounted thereon.

7. The semiconductor package substrate as set forth in claim 6, wherein the sealing member is made of an epoxy molded compound.

8. A method for manufacturing a semiconductor package substrate, the method comprising:
forming a solder resist layer having openings exposing connection pads on a substrate having the connection pads; and
forming a roughness layer on the solder resist layer.

9. The method as set forth in claim 8, wherein the solder resist layer includes a semiconductor chip mounting area and an exposure area in which a surface thereof is exposed to the outside, and the roughness layer is formed in the exposure area.

10. The method as set forth in claim 8, wherein the forming of the roughness layer is performed by spraying a liquid resin on the solder resist layer.

11. The method as set forth in claim 10, wherein the spraying is performed by an inkjet.

12. The method as set forth in claim 10, wherein the resin is epoxy or polyimide.

13. The method as set forth in claim 8, further comprising, after the forming of the roughness layer, forming bumps on the connection pads;
mounting a semiconductor chip on the bumps; and
molding the substrate having the semiconductor chip mounted thereon using a sealing member.

14. The method as set forth in claim 13, wherein the sealing member is made of an epoxy molded compound.
